(19) United States
(12) Patent Application Publication
(10) Pub. No.: US 2008/0006930 A1
(43) Pub. Date: Jan. 10, 2008

(54) SEMICONDUCTOR PACKAGE

(75) Inventor: Makoto ICHIDA, Yokohama-Shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/763,776

(22) Filed: Jun. 15, 2007

(30) Foreign Application Priority Data
Jun. 22, 2006 (JP) 2006-172399

(51) Int. Cl. H01L 23/12

(52) U.S. Cl. 257/700

(57) ABSTRACT

A semiconductor package, has a multilayer wiring board that has a first wiring layer on which an inner lead, a first signal wire for transmission of a desired signal, a power supply ring, and a ground ring are formed, a second wiring layer that has a first solder ball, a second solder ball, and a third solder ball disposed on the surface thereof, a power supply wiring layer that is disposed between said first wiring layer and said second wiring layer and electrically connected to said power supply ring and said first solder ball, and a ground wiring layer that is disposed between said first wiring layer and said second wiring layer and electrically connected to said ground ring and said second solder ball; and a semiconductor chip that is mounted on said first wiring layer and on which a signal pad for input/output of a desired signal connected to said inner lead by a bonding wire, a power supply pad connected to said power supply ring by a bonding wire, and a ground pad connected to said ground ring by a bonding wire are disposed on the upper surface thereof, wherein said first solder ball is to be connected to a power supply potential, said second solder ball is to be connected to a ground potential, said third solder ball is for signal input/output, a second signal wire is formed on any of said second wiring layer, said power supply wiring layer and said ground wiring layer, and said inner lead and the third solder ball are electrically connected to each other via said second signal wire.

### CROSS-REFERENCE TO RELATED APPLICATION

This application is based upon and claims the benefit of priority from the prior Japanese Patent Application No. 2006-172399, filed on Jun. 22, 2006, the entire contents of which are incorporated herein by reference.

### BACKGROUND OF THE INVENTION

1. Field of the Invention

The present invention relates to a semiconductor package in which a semiconductor chip is mounted.

2. Background Art

Recently, the integration density and speed of LSI circuits have increased, and accordingly, the number of input/output pins increases, and the switching time of output signals is rapidly reduced. In order to increase the number of terminal electrodes, there have been proposed semiconductor packages, such as a ball grid array (BGA), that have an encapsulated semiconductor chip.

In such a semiconductor package, an instantaneous large current or a voltage drop (a counter electromotive force) occurs in signal wiring because of the inductance among an inner lead, a pad and a solder ball. For example, in the case where the semiconductor chip has a macro cell whose electrical connections can be changed by a circuit blowout by Joule heat, a desired electrical connection cannot be established because of the voltage drop.

A conventional semiconductor package of the type described above has an internal configuration in which a signal wire connected to a output buffer, and one signal Vss wire or Vcc wire connected to a output buffer are adjacent to each other, in a semiconductor chip are alternately arranged on a relay board in the package (see Japanese Patent Laid-Open Publication No. 7-38011, for example).

According to this conventional technique, a counter current occurs between the wires on the relay board, and the effective inductance due to the mutual inductance can be reduced. However, according to this conventional technique, the relay board has to be additionally provided, and the wiring configuration is complicated.

Furthermore, for another conventional semiconductor package (a BGA package), the length of the leads for connection of the power supply layer and the ground layer is minimized to reduce the inductance of the leads, and the ground lead and the power supply lead are planarized to reduce the apparent inductance of the leads (see Japanese Patent Laid-Open Publication No. 8-78573, for example).

However, the conventional technique does not refer to the length of the signal wiring on the signal wiring layer and is not intended to reduce the inductance of the signal wiring.

As described above, the conventional techniques described above have a problem that the inductance cannot be reduced without increasing the complexity of the wiring configuration, and occurrence of an instantaneous large current or a voltage drop (counter electromotive force) in the signal wiring cannot be prevented.

### SUMMARY OF THE INVENTION

According to one aspect of the present invention, there is provided: a semiconductor package, comprising a multilayer wiring board that has a first wiring layer on which an inner lead, a first signal wire for transmission of a desired signal, a power supply ring, and a ground ring are formed, a second wiring layer that has a first solder ball, a second solder ball, and a third solder ball disposed on the surface thereof, a power supply wiring layer that is disposed between said first wiring layer and said second wiring layer and electrically connected to said power supply ring and said first solder ball, and a ground wiring layer that is disposed between said first wiring layer and said second wiring layer and electrically connected to said ground ring and said second solder ball; and a semiconductor chip that is mounted on said first wiring layer and on which a signal pad for input/output of a desired signal connected to said inner lead by a bonding wire, a power supply pad connected to said power supply ring by a bonding wire, and a ground pad connected to said ground ring by a bonding wire are disposed on the upper surface thereof, wherein said first solder ball is to be connected to a power supply potential, said second solder ball is to be connected to a ground potential, said third solder ball is for signal input/output, a second signal wire is formed on any of said second wiring layer, said power supply wiring layer and said ground wiring layer, and said inner lead and the third solder ball are electrically connected to each other via said second signal wire.

According to another aspect of the present invention, there is provided: a multilayer wiring board, comprising a first wiring layer on which an inner lead, a first signal wire for transmission of a desired signal, a power supply ring, and a ground ring are formed; a second wiring layer that can have a first solder ball, a second solder ball, and a third solder ball disposed on the surface thereof; a power supply wiring layer that is disposed between said first wiring layer and said second wiring layer, is electrically connected to said power supply ring, and is to be electrically connected to said first solder ball; and a ground wiring layer that is disposed between said first wiring layer and said second wiring layer, is electrically connected to said ground ring, and is to be electrically connected to said second solder ball, wherein a second signal wire is formed on any of said second wiring layer, said power supply wiring layer and said ground wiring layer.

### BRIEF DESCRIPTION OF THE DRAWINGS

FIG. 1 is a cross-sectional view showing a configuration of essential parts of a semiconductor package according to an embodiment 1 of the present invention;

FIG. 2 is a plan view showing essential parts of the semiconductor shown in FIG. 1;

FIG. 3 is a plan view showing essential parts of a power supply wiring layer of the semiconductor package shown in FIG. 1;

FIG. 4 is a cross-sectional view of the semiconductor package taken along the line A-A in FIG. 3. In FIG. 2, illustration of a molded resin is omitted for the purpose of explanation;

FIG. 5 is a plan view showing essential parts of a power supply wiring layer of a semiconductor package according to the embodiment 2, which is an aspect of the present invention;

FIG. 6 is a plan view showing essential parts of a power supply wiring layer of a semiconductor package according to the embodiment 3, which is an aspect of the present invention; and

FIG. 7 is a plan view showing essential parts of a power supply wiring layer of a semiconductor package 100 according to the embodiment 4, which is an aspect of the present invention.

### DETAILED DESCRIPTION

In the following, embodiments of the present invention will be described with reference to the drawings. In the embodiments, cases where the present invention is applied to a plastic ball grid array (PBGA) package will be described.

### Embodiment 1

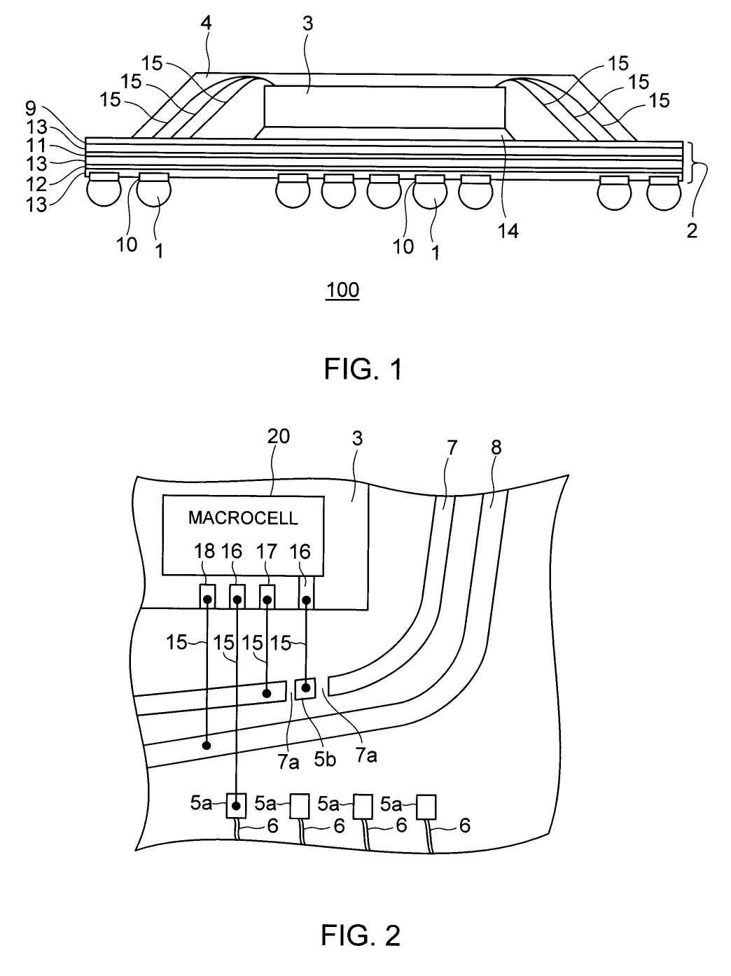

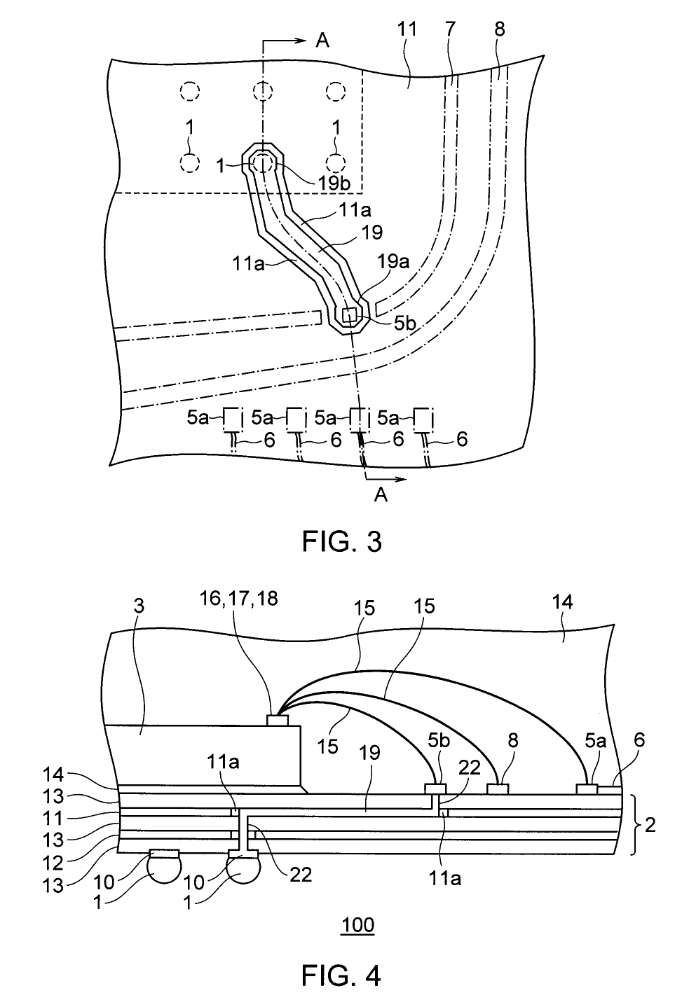

FIG. 1 is a vertical cross-sectional view showing a configuration of essential parts of a semiconductor package according to an embodiment 1 of the present invention. FIG. 2 is a plan view showing essential parts of the semiconductor shown in FIG. 1. FIG. 3 is a plan view showing essential parts of a power supply wiring layer of the semiconductor package shown in FIG. 1. FIG. 4 is a cross-sectional view of the semiconductor package taken along the line A-A in FIG. 3. In FIG. 2, illustration of a molded resin is omitted for the purpose of explanation.

As shown in FIGS. 1 to 4, a semiconductor package 100 has a plurality of solder balls 1, a multilayer wiring board 2 to the lower surface of which the solder balls are attached, a semiconductor chip 3 mounted on the upper surface of the multilayer wiring board 2, and a molded resin 4 that encapsulates the semiconductor chip 3 on the upper surface of the multilayer wiring board 2.

The multilayer wiring board 2 includes a first wiring layer 9 on which inner leads 5a, 5b, a first signal wire 6 for transmission of a desired signal, a power supply ring 7 and a ground ring 8 are formed, and a second wiring layer 10 that has the solder balls 1 disposed on the lower surface thereof and is electrically connected to the inner leads 5a, 5b and to the solder balls 1 for input/output of a desired signal.

The first signal wire 6 has a length of 10 to 20 mm.

The multilayer wiring board 2 further includes a power supply wiring layer 11 that is disposed between the first wiring layer 9 and the second wiring layer 10 and electrically connected to the power supply ring 7 and a solder ball 1 to be connected to a power supply potential, and a ground wiring layer 12 that is disposed between the first wiring layer 9 and the second wiring layer 10 and electrically connected to the ground ring 8 and a solder ball 1 to be connected to a ground potential.

Insulating plastic boards 13 are disposed between the wiring layers 9, 10, 11 and 12. The plastic boards 13 have a contact hole penetrating therethrough, and a contact hole wire 22 passes through the contact hole to electrically connect the wiring layers 9, 10, 11 and 12 to each other.

The semiconductor chip 3 is mounted on the first wiring layer 9 of the multilayer wiring board 2 and fixed by an adhesive 14 or the like.

On the upper surface of the semiconductor chip 3, there are disposed signal pads 16 for input/output of a desired signal that are connected to the inner leads 5a, 5b by bonding wires 15, a power supply pad 17 that is connected to the power supply ring 7 by a bonding wire 15, and a ground pad 18 that is connected to the ground ring 8 by a bonding wire 15.

The semiconductor chip 3 includes a macro cell 20 whose electrical connections can be changed by causing a circuit blowout by Joule heat. At least one signal pad 16 is used for inputting a signal for writing to the macro cell 20.

The distance between the power supply ring 7 (and the ground ring 8) and the signal pads 16 is 1 to 2 mm.

The power supply ring 7 has a gap 7a. The inner lead 5b is formed in the gap 7a. Alternatively, a gap may be formed in the ground ring 8, and the inner lead 5b may be formed in the gap.

A second signal wire 19 is formed on the power supply wiring layer 11. The second signal wire 19 is electrically connected to the inner lead 5b via the contact hole wire 22 at one end 19a thereof and to a solder ball 1 via the contact hole wire 22 at the other end 19b thereof. That is, the inner lead 5b and the solder ball 1 are electrically connected to each other via the second signal wire 19. Furthermore, a gap 11a is formed between the second signal wire 19 and the part of the power supply wiring layer 11 connected to the power supply potential, and the gap 11a insulates the second signal wire 19 and the power supply wiring layer 11 from each other.

Alternatively, the second signal wire may be formed on the second wiring layer 10 or the ground wiring layer 12.

In this way, the second signal wire 19 is formed on any of the second wiring layer 10, the power supply wiring layer 11 and the ground wiring layer 12.

Thus, the second signal wire 19 can be formed more easily than the case the second signal wire 19 is formed on the first wiring layer 9 on which the inner leads 5a, 5b, the first signal wire 6 for transmission of a desired signal, the power supply ring 7, the ground ring 8 and the like are intricately arranged.

Furthermore, the second wiring layer 10, the power supply wiring layer 11 and the ground wiring layer 12 have a larger space available for formation of signal wiring than the first wiring layer 9, and therefore, the second signal wire 19 can be thicker than the first signal wire 6 formed on the first wiring layer 9.

As a result, the inductance of the signal wiring can be reduced.

The solder ball 1 electrically connected to the inner lead 5b formed in the gap 7a in the power supply ring 7 (or the ground ring 8) is disposed in a thermal ball region, which is closer to the center of the multilayer wiring board 2 than the region in which the power supply ring 7 (or the ground ring 8) is formed.

The distance between the inner lead 5b and the solder ball 1 disposed closer to the center of the multilayer wiring board 2 is 1 to 2 mm. On the other hand, the distance between the inner lead 5a and the solder ball 1 disposed at the outer side thereof is 10 to 20 mm.

Thus, the second signal wire 19 can be shorter if the second signal wire 19 is connected to the solder ball 1 disposed closer to the center than if the second signal wire 19 is connected to the solder ball 1 disposed at the outer side.

Thus, the inductance of the signal wiring can be reduced.

Furthermore, the distance between the inner lead 5a and the signal pad 16 is 3 to 4 mm.

Therefore, the distance between the signal pad 16 and the inner lead 5b is about 2 mm shorter than the distance between the signal pad 16 and the inner lead 5a, and thus, the length of the bonding wire 15 is reduced.

Thus, the inductance of the bonding wire 15 can be reduced.

Here, as described above, the electrical connections of the macro cell 20 can be changed by blowing a circuit by Joule heat. When a circuit blowout occurs, a large current (instantaneous current) momentarily flows through the signal pad 16 for writing. Circuit blowout requires a certain voltage, and if a large voltage drop occurs, the circuit blowout can fail. If the instantaneous current described above flows, a counter electromotive force of “−L(di/dt)” is produced.

The counter electromotive force can be reduced by reducing the inductance component “L”.

That is, if the inductances of the bonding wire 15 electrically connected to the signal pad 16 and the second signal wire 19 are reduced as described above, the voltage drop described above is reduced.

In this way, the macro cell 20, which is sensitive to a change in instantaneous current, can be desired in a desired way by reducing the inductance components of the semiconductor package.

As described above, according to this embodiment, the inductance of the semiconductor package can be reduced without increasing the complexity of the wiring configuration, and occurrence of an instantaneous large current or a voltage drop in the bonding wires or signal wires can be prevented.

The positions of the power supply ring 7 and the ground ring 8 can be interchanged.

In this embodiment described above, the multilayer wiring board 2 includes four layers, the first wiring layer 9, the second wiring layer 10, the power supply wiring layer 11 and the ground wiring layer 12. However, the multilayer wiring board 2 may include five or more wiring layers. For example, the multilayer wiring board 2 may further include a signal wiring layer other than the first wiring layer 9, the second wiring layer 10, the power supply wiring layer 11 and the ground wiring layer 12.

### Embodiment 2

In the embodiment described above, the second signal wire is formed on any of the second wiring layer, the power supply wiring layer and the ground wiring layer and electrically connects the inner lead formed in the gap in the power supply ring (or the ground ring) and the solder ball to each other.

However, the inner lead may be formed in another region as far as the inductance of the second signal wire is smaller than the inductance of the first signal wire.

Thus, in an embodiment 2, there will be described an arrangement in which a second signal wire is connected to an inner lead 5a, which can be connected to a first signal wire.

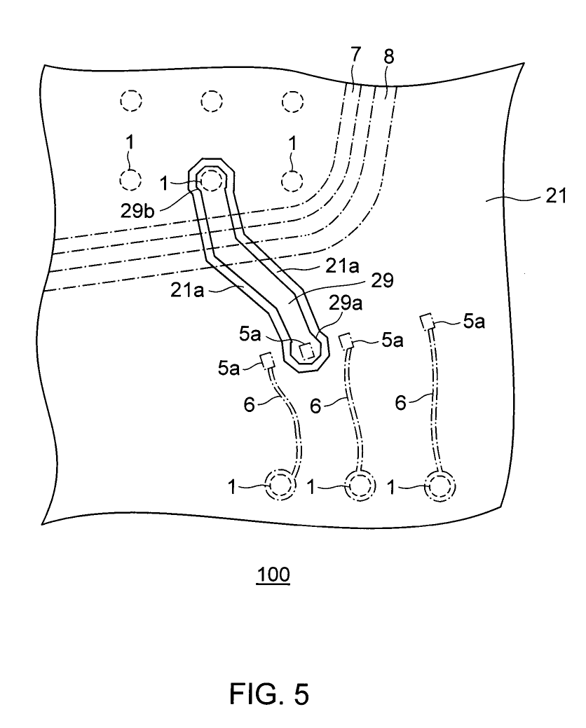

FIG. 5 is a plan view showing essential parts of a power supply wiring layer of a semiconductor package 100 according to the embodiment 2, which is an aspect of the present invention. The components denoted by the same reference numerals as those in the embodiment 1 are the same as those in the embodiment 1. The arrangement excluding the second signal wire formed on the power supply wiring layer, and the bonding wire, the contact hole wire and the inner lead connected to the second signal wire is the same as that in the embodiment 1.

As shown in FIG. 5, a second signal wire 29 is formed on a power supply wiring layer 21. The second signal wire 29 is electrically connected to an inner lead 5a via a contact hole wire 22 at one end 29a thereof and to a solder ball 1 via a contact hole wire 22 at the other end 29b thereof. That is, the inner lead 5a and the solder ball 1 are electrically connected to each other via the second signal wire 29. Furthermore, a gap 21a is provided between the second signal wire 29 and the part of the power supply wiring layer 21 connected to a power supply potential, and the gap 21a insulates the second signal wire 29 and the power supply wiring layer 21 from each other.

As in the embodiment 1, alternatively, the second signal wire may be formed on a second wiring layer 10 or a ground wiring layer 12.

In this way, the second signal wire 29 is formed on any of the second wiring layer 10, the power supply wiring layer 21 and the ground wiring layer 12.

Thus, the second signal wire 29 can be formed more easily than the case the second signal wire 29 is formed on the first wiring layer 9 on which the inner lead 5a, a first signal wire 6 for transmission of a desired signal, a power supply ring 7, a ground ring 8 and the like are intricately arranged.

Furthermore, the second wiring layer 10, the power supply wiring layer 21 and the ground wiring layer 12 have a larger space available for formation of signal wiring than the first wiring layer 9, and therefore, the second signal wire 29 can be thicker than the first signal wire 6 formed on the first wiring layer 9.

As a result, the inductance of the signal wiring can be reduced.

Compared with the embodiment 1, the distance of the inner lead from the signal pad and the solder ball increases, and thus, the length of the bonding wire and the second signal wire also increases.

As described above, according to this embodiment, the inductance of the semiconductor package can be reduced without increasing the complexity of the wiring configuration, and occurrence of an instantaneous large current or a voltage drop in bonding wires or signal wires can be prevented.

As in the embodiment 1, the positions of the power supply ring 7 and the ground ring 8 can be interchanged.

### Embodiment 3

In the embodiment 2 described above, the second signal wire is formed on any of the second wiring layer, the power supply wiring layer and the ground wiring layer and electrically connects the inner lead that can be connected to the first signal wire and the solder ball disposed closer to the center of the multilayer wiring board 2 to each other.

However, the second signal wire may be connected to a conventionally used solder ball that is disposed at the outer side of the power supply ring and the ground ring. In this case, the inductance of the signal wiring can be reduced at least compared with a case where the first signal wire is connected to the solder ball.

Thus, in an embodiment 3, there will be described an arrangement in which a second signal wire is connected to a solder ball disposed at the outer side thereof.

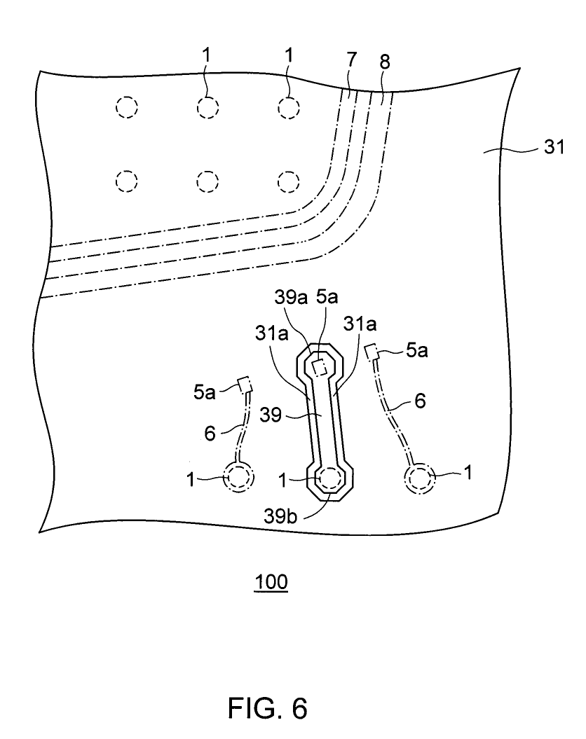

FIG. 6 is a plan view showing essential parts of a power supply wiring layer of a semiconductor package 100 according to the embodiment 3, which is an aspect of the present invention. The components denoted by the same reference numerals as those in the embodiment 1 are the same as those in the embodiment 1. The arrangement excluding the second signal wire formed on the power supply wiring layer, and the bonding wire, the contact hole wire and the inner lead connected to the second signal wire is the same as that in the embodiment 1.

As shown in FIG. 6, a second signal wire 39 is formed on a power supply wiring layer 31. The second signal wire 39 is electrically connected to an inner lead 5a via a contact hole wire 22 at one end 39a thereof and to a conventionally used solder ball 1 for input/output of a desired signal that is disposed at the outer side of a power supply ring 7 and a ground ring 8 via a contact hole wire 22 at the other end 39b thereof. That is, the inner lead 5a and the solder ball 1 are electrically connected to each other via the second signal wire 39. Furthermore, a gap 31a is provided between the second signal wire 39 and the part of the power supply wiring layer 31 connected to a power supply potential, and the gap 31a insulates the second signal wire 39 and the power supply wiring layer 31 from each other. Unlike the embodiments 1 and 2, the signal input to or output from each solder ball 1 need not be changed from that in the conventional arrangement.

As in the embodiment 1, alternatively, the second signal wire may be formed on a second wiring layer 10 or a ground wiring layer 12.

In this way, the second signal wire 39 is formed on any of the second wiring layer 10, the power supply wiring layer 31 and the ground wiring layer 12.

Thus, the second signal wire 39 can be formed more easily than the case the second signal wire 39 is formed on the first wiring layer 9 on which the inner lead 5a, a first signal wire 6 for transmission of a desired signal, the power supply ring 7, the ground ring 8 and the like are intricately arranged.

Furthermore, the second wiring layer 10, the power supply wiring layer 31 and the ground wiring layer 12 have a larger space available for formation of signal wiring than the first wiring layer 9, and therefore, the second signal wire 39 can be thicker than the first signal wire 6 formed on the first wiring layer 9.

As a result, the inductance of the signal wiring can be reduced.

Compared with the embodiment 1, the distance of the inner lead from the signal pad and the solder ball increases as in the embodiment 2, and thus, the length of the bonding wire and the second signal wire also increases.

As described above, according to this embodiment, the inductance of the semiconductor package can be reduced without increasing the complexity of the wiring configuration, and occurrence of an instantaneous large current or a voltage drop in bonding wires or signal wires can be prevented.

As in the embodiment 1, the positions of the power supply ring 7 and the ground ring 8 can be interchanged.

### Embodiment 4

In the embodiment 3 described above, the second signal wire is formed on any of the second wiring layer, the power supply wiring layer and the ground wiring layer and electrically connects the inner lead that can be connected to the first signal wire and the solder ball disposed at the outer side of the inner lead to each other.

However, the second signal wire may be connected to an inner lead disposed in a gap in the power supply ring (or the ground ring) and to a conventionally used solder ball that is disposed at the outer side of the power supply ring and the ground ring. In this case, the inductance of the signal wiring can be reduced at least compared with a case where the first signal wire is connected to the inner lead and the solder ball.

Thus, in an embodiment 3, there will be described an arrangement in which a second signal wire is connected to a solder ball disposed at the outer side thereof.

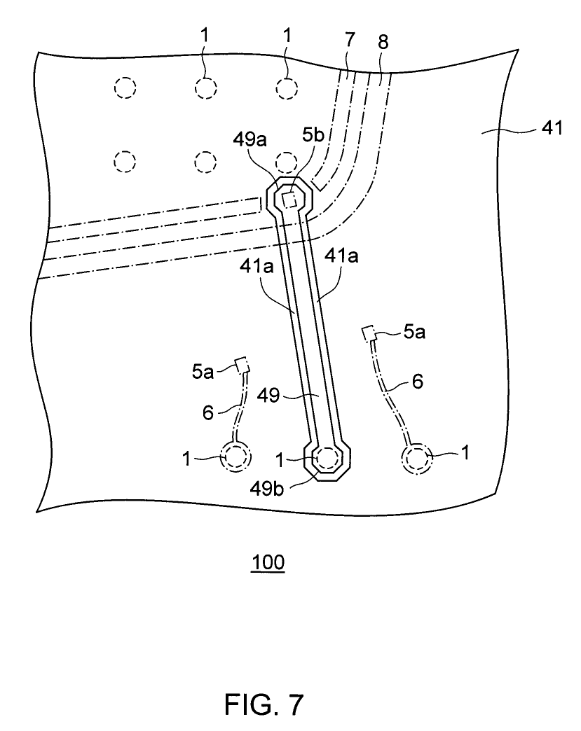

FIG. 7 is a plan view showing essential parts of a power supply wiring layer of a semiconductor package 100 according to the embodiment 4, which is an aspect of the present invention. The components denoted by the same reference numerals as those in the embodiment 1 are the same as those in the embodiment 1. The arrangement excluding the second signal wire formed on the power supply wiring layer, and the bonding wire, the contact hole wire and the inner lead connected to the second signal wire is the same as that in the embodiment 1.

As shown in FIG. 7, a second signal wire 49 is formed on a power supply wiring layer 41. The second signal wire 49 is electrically connected to an inner lead 5b via a contact hole wire 22 at one end 49a thereof and to a conventionally used solder ball 1 for input/output of a desired signal that is disposed at the outer side of a power supply ring 7 and a ground ring 8 via a contact hole wire 22 at the other end 49b thereof. That is, the inner lead 5b and the solder ball 1 are electrically connected to each other via the second signal wire 49. Furthermore, a gap 41a is provided between the second signal wire 49 and the part of the power supply wiring layer 41 connected to a power supply potential, and the gap 41a insulates the second signal wire 49 and the power supply wiring layer 41 from each other. Unlike the embodiments 1 and 2, the signal input to or output from each solder ball 1 need not be changed from that in the conventional arrangement.

As in the embodiment 1, alternatively, the second signal wire may be formed on a second wiring layer 10 or a ground wiring layer 12.

In this way, the second signal wire 49 is formed on any of the second wiring layer 10, the power supply wiring layer 41 and the ground wiring layer 12.

Thus, the second signal wire 49 can be formed more easily than the case the second signal wire 49 is formed on the first wiring layer 9 on which the inner lead 5b, a first signal wire 6 for transmission of a desired signal, the power supply ring 7, the ground ring 8 and the like are intricately arranged.

Furthermore, the second wiring layer 10, the power supply wiring layer 41 and the ground wiring layer 12 have a larger space available for formation of signal wiring than the first wiring layer 9, and therefore, the second signal wire 49 can be thicker than the first signal wire 6 formed on the first wiring layer 9.

As a result, the inductance of the signal wiring can be reduced.

Compared with the embodiment 3, the distance of the inner lead from the solder ball increases, and thus, the length of the second signal wire increases. The length of the bonding wire decreases.

As described above, according to this embodiment, the inductance of the semiconductor package can be reduced without increasing the complexity of the wiring configuration, and occurrence of an instantaneous large current or a voltage drop in bonding wires or signal wires can be prevented.

As in the embodiment 1, the positions of the power supply ring 7 and the ground ring 8 can be interchanged.

What is claimed is:

1. A semiconductor package, comprising:
a multilayer wiring board that has
a first wiring layer on which an inner lead, a first signal wire for transmission of a desired signal, a power supply ring, and a ground ring are formed,
a second wiring layer that has a first solder ball, a second solder ball, and a third solder ball disposed on the surface thereof,
a power supply wiring layer that is disposed between said first wiring layer and said second wiring layer and electrically connected to said power supply ring and said first solder ball, and
a ground wiring layer that is disposed between said first wiring layer and said second wiring layer and electrically connected to said ground ring and said second solder ball; and
a semiconductor chip that is mounted on said first wiring layer and on which a signal pad for input/output of a desired signal connected to said inner lead by a bonding wire, a power supply pad connected to said power supply ring by a bonding wire, and a ground pad connected to said ground ring by a bonding wire are disposed on the upper surface thereof,
wherein said first solder ball is to be connected to a power supply potential,
said second solder ball is to be connected to a ground potential,
said third solder ball is for signal input/output,
a second signal wire is formed on any of said second wiring layer, said power supply wiring layer and said ground wiring layer, and
said inner lead and the third solder ball are electrically connected to each other via said second signal wire.

2. The semiconductor package according to claim 1, wherein said semiconductor chip includes a macro cell whose electrical connections are capable of being changed by a circuit blowout by Joule heat, and
said signal pad is a pad used for input of a signal for writing to said macro cell.

3. The semiconductor package according to claim 1, wherein said second signal wire is thicker than said first signal wire formed on said first wiring layer.

4. The semiconductor package according to claim 1, wherein a gap is formed in said power supply ring or said ground ring, and
said inner lead is formed in said gap.

5. The semiconductor package according to claim 1, wherein said third solder ball electrically connected to said inner lead is disposed closer to the center of said multilayer wiring board than a region in which said power supply ring or said ground ring is formed.

6. The semiconductor package according to claim 1, wherein said second signal wire is formed in said power supply or said ground wiring layer.

7. A multilayer wiring board, comprising:
a first wiring layer on which an inner lead, a first signal wire for transmission of a desired signal, a power supply ring, and a ground ring are formed;
a second wiring layer that can have a first solder ball, a second solder ball, and a third solder ball disposed on the surface thereof;
a power supply wiring layer that is disposed between said first wiring layer and said second wiring layer, is electrically connected to said power supply ring, and is to be electrically connected to said first solder ball; and
a ground wiring layer that is disposed between said first wiring layer and said second wiring layer, is electrically connected to said ground ring, and is to be electrically connected to said second solder ball,
wherein a second signal wire is formed on any of said second wiring layer, said power supply wiring layer and said ground wiring layer.

8. The multilayer wiring board according to claim 7, wherein said second signal wire is thicker than said first signal wire formed on said first wiring layer.

9. The multilayer wiring board according to claim 7, wherein a gap is formed in said power supply ring or said ground ring, and
said inner lead is formed in said gap.

10. The multilayer wiring board according to claim 7, wherein said second signal wire is formed in said power supply or said ground wiring layer.
